(19) United States
(12) Patent Application Publication
(10) Pub. No.: US 2026/0096352 A1
(43) Pub. Date: Apr. 2, 2026

(54) VERTICAL III-V HALL SENSOR

(71) Applicant: TDK-Micronas GmbH, Freiburg (DE)

(72) Inventors: Martin CORNILS, Freiburg (DE); Maria-Cristina VECCHI, Freiburg (DE); Holger EGGERS, Voerstetten (DE); Dag BEHAMMER, Ulm (DE)

(73) Assignee: TDK-Micronas GmbH, Freiburg (DE)

(21) Appl. No.: 19/413,677

(22) Filed: Dec. 9, 2025

Related U.S. Application Data
(63) Continuation of application No. PCT/EP2024/000010, filed on Feb. 19, 2024.

(30) Foreign Application Priority Data
Jun. 9, 2023 (DE) 10 2023 002 342.6

(51) Int. Cl. H10N 52/00; G01R 33/07; H10N 52/85

(52) U.S. Cl. CPC H10N 52/101; G01R 33/077; H10N 52/85

(57) ABSTRACT

A vertical III-V Hall sensor, which has a substrate layer with an upper side and an underside, and a first insulating layer formed on the substrate layer, and a III-V semiconductor layer formed on the insulating layer, and a second insulating layer formed on the III-V semiconductor layer, the second insulating layer being structured and having at least three openings designed as contact regions, and the III-V semiconductor layer having a length formed in the X direction and a width formed in the Y direction, and the at least three contact regions being arranged along a straight line, and the III-V semiconductor layer having an n doping, and the III-V semiconductor layer having a peripheral insulation.

This nonprovisional application is a continuation of International Application No. PCT/EP2024/000010, which was filed on Feb. 19, 2024, and which claims priority to German Patent Application No. 10 2023 002 342.6, which was filed in Germany on Jun. 9, 2023, and which are both herein incorporated by reference.

### BACKGROUND OF THE INVENTION

### Field of the Invention

Vertical Hall sensors are known in silicon technology. However, due to the completely different III-V material properties and entirely divergent technological requirements, and, in particular, due to the manufacturing methods, which are completely incompatible with silicon, Hall sensors of this type using III-V materials have not been known until now.

### Description of the Background Art

Various III-V Hall sensors are known from CN 102 520 376 A for measuring the three components of a magnetic field. To measure magnetic fields running in parallel to a substrate surface, a column-shaped Hall sensor structure is disclosed, which is arranged perpendicularly on the substrate surface. The column-shaped structure is contacted at the two end faces and elsewhere.

A III-V Hall sensor is also known from EP 3 216 057 B1 (which corresponds to US 2017/0328962), which uses a 2DEG quantum well structure. Further III-V Hall sensors are known from EP 0 204 135 A1 (which corresponds to U.S. Pat. No. 4,929,993), CN 109 244 234 B, DE 10 2011 002580 A1, and CN 105 261 698 A.

### SUMMARY OF THE INVENTION

It is therefore an object of the present invention to provide a device which refines the prior art.

According to the subject manner of the invention, a vertical III-V Hall sensor is provided, which has a substrate layer with an upper side and an underside.

A first insulating layer is formed on the substrate layer, and a III-V semiconductor layer is formed on the insulating layer, and a second insulating layer is formed on the III-V semiconductor layer.

The second insulating layer is provided with a structured design and has at least three openings designed as contact regions.

The III-V semiconductor layer has a length formed in the X direction and a width formed in the Y direction.

The at least three contact regions are arranged along a straight line on an upper side of the III-V semiconductor layer formed in the direction of the second insulating layer. The III-V semiconductor layer has an n doping.

It should be noted that the vertical III-V Hall sensor has a main extension surface in parallel to the substrate surface.

The III-V semiconductor layer furthermore has a peripheral insulation.

It should be noted that the III-V semiconductor layers are manufactured by means of an epitaxy process, generally using metal-organic precursors, in particular, with the aid of an MOVPE or an MBE system.

An advantage is that, surprisingly, vertical Hall sensors may advantageously be manufactured reliably with a high degree of sensitivity even using III-V materials. Up to now, those skilled in the art have assumed that the manufacturing of a vertical III-V Hall sensor would not be able to be implemented, due to the completely different technological requirements of III-V materials compared to silicon. Among the reasons is the fact that a doping with the aid of an implantation is not possible. Thermal passivations, such as an oxide growth, etc., are also not possible.

Another advantage is that cost-effective vertical III-V Hall sensors may be manufactured using III-V standard processes, due to their simple design.

The aforementioned III-V semiconductor layers can be grown monolithically and in a manner lattice-matched to each other. It should be noted that the term “monolithically” may be understood to be a manufacturing process, in which the III-V semiconductor layers are deposited by means of a temporally continuous epitaxy process. In other words, the III-V semiconductor wafer is not removed from the epitaxy system during the layer deposition. In particular, no semiconductor bond is formed between the III-V semiconductor layers.

All layers can be manufactured by means of gas phase epitaxy in an MOVPE system, preferably in a lattice-matched manner.

The semiconductor wafer, i.e., the substrate, can have a diameter of 100 mm, or diameter of 150 mm, or a larger diameter.

The III-V semiconductor layer can have a uniform thickness. further, the III-V semiconductor layer can have a uniform thickness in the entire region of the vertical III-V Hall sensor.

The III-V semiconductor layer can have a uniform thickness at least or exclusively in the region of the III-V Hall sensor. The III-V semiconductor layer can have a uniform thickness at least between the contact regions and including the contact regions.

The first insulating layer and/or the second insulating layer can be made from a III-V material. Also, the first insulating layer and/or the second insulating layer can comprise a III-V material.

The first insulating layer and/or the second insulating layer may not be doped. It should be noted that the term “exclusively” can be understood to be an intentional doping. In this regard, it should be noted that, an unintentional doping generally takes place at least using carbon when using metal-organic precursors in a manufacturing of the III-V layers by means of gas phase epitaxy in an MOVPE system. It should be noted that the unintentional doping is generally in a range between 1·10¹⁴ N/cm³ and 1·10¹⁵ N/cm³.

It should furthermore be noted that an unintentional doping may also unavoidably occur by a selection of the process parameter during the epitaxy. It should be noted that, by selecting the process parameters, the level of the unintentional doping above an unintentional carbon minimum doping may be influenced in a range greater than 1·10¹⁴ N/cm³.

The band gap of the first insulating layer and/or the second insulating layer can be designed in each case to be larger than the band gap of the III-V semiconductor layer. It is understood that an insulating space-charge zone forms by the use of undoped high band materials, in each case at the boundary surface of the III-V semiconductor layer.

The thickness of the first insulating layer formed in a III-V material and/or the thickness of the second insulating layer formed in a III-V material can be in a range between 2 nm and 100 nm. The thickness can be in a range between 10 nm and 80 nm or in a range between 20 nm and 60 nm. Further, the thickness of the first insulating layer and/or the thickness of the second insulating layer can be greater than 10 nm and less than 500 nm.

The first insulating layer and/or the second insulating layer can comprise(s) at least the elements InGaP, or the first insulating layer and/or the second insulating layer (IS2) comprise(s) at least one of the elements In, Ga, and/or P. It is understood that the first insulating layer and/or the second insulating layer may have further III-V elements, in particular Al or P.

The first insulating layer and/or the second insulating layer can be made up of InGaP.

The second insulating layer can comprise a silicon oxide and/or a silicon nitride.

An n-doped structured InGaP layer is arranged as a metallically conductive layer on the upper side of the III-V semiconductor layer and connected to the III-V semiconductor layer in a materially bonded manner. The doping of the InGaP layer is in a range between 1·10¹⁸ cm⁻³ and 1·10²⁰ cm⁻³. In another refinement, the highly conductive InGaP layer is arranged exclusively under a metal contact formed in the contact opening.

The doping can be uniform or variable over the thickness of the III-V semiconductor layer. In one refinement, the III-V semiconductor layer has a lower doping at the boundary surface to the first insulating layer than in the direction of the second insulating layer.

The doping of the III-V semiconductor layer an be in a range between 1·10¹⁴ 1/cm³ and 5·10¹⁷ 1/cm³ or in a range between 5·10¹⁴ 1/cm³ and 1·10¹⁶ 1/cm³ or in a range between 1·10¹⁵ 1/cm³ and 5·10¹⁵ 1/cm³. It is understood that, to achieve the highest possible mobility, the doping of the III-V semiconductor layer should be below 5·10¹⁶ 1/cm³, at least in a predominant part of the thickness.

The III-V semiconductor layer can have a thickness in a range between 0.5 μm and 50 μm or in a range between 1·0 μm and 20 μm or in a range between 3.0 μm and 10 μm.

The ratio of length to width in the III-V semiconductor layer can be greater than or equal to 1 or in a range between 1 and 50.

The vertical III-V Hall sensor can comprise or is made up of a quadrilateral geometry. It can be understood that, with a ratio of 1 between the length and width, the quadrangle is designed as a square.

The length can be greater than the width, the length being at least twice the size of the width.

The vertical III-V Hall sensor can comprise a more than quadrilateral geometry. In particular, the vertical III-V Hall sensor has a hexagonal or octagonal geometry.

The width of the III-V semiconductor layer can be in a range between 1 μm and 20 μm or in a range between 3 μm and 10 μm.

If the length is double the size of the width, it is understood that the length is greater than or equal to 2 μm or greater than or equal to 6 μm or greater than or equal to 20 μm or greater than or equal to 40 μm.

The length can be less than 100 μm or less than 50 μm or less than 30 μm or less than 20 μm.

The III-V semiconductor layer can have a uniform stoichiometry.

The III-V semiconductor layer can comprise GaAs or InGaAs, or the III-V semiconductor layer is made up of GaAs or InGaAs or InSb or InAs or GaSb.

The III-V semiconductor layer of the vertical III-V Hall sensor can have a peripheral region produced by means of a hydrogen implantation as insulation.

The insulation produced by means of hydrogen implantation can be designed in such a way that the entire III-V semiconductor layer within the peripheral region is completely electrically insulated against the surrounding regions of the III-V semiconductor layer.

The III-V semiconductor layer can have a trench as insulation. The trench can be produced by means of a mesa etching. In one refinement, the side walls, i.e. the perpendicular or nearly perpendicular walls, of the vertical III-V Hall sensor are passivated and/or covered by an insulating layer. It is understood that the term “peripherally formed” designates an annular closed structure.

The III-V semiconductor layer can be cut all the way through by the trench. In other words, the first insulating layer is formed in the base region of the trench. This creates a first region in the III-V semiconductor layer which is electrically insulated from the further regions of the III-V semiconductor layer, in that the first insulating layer is formed on the underside of the III-V semiconductor layer.

The trench can be filled with an insulating material, preferably with a dielectric material, for example with a PECVD oxide and/or a silicon nitride.

The distances between two directly consecutive contact regions can be designed to be the same or different.

The vertical III-V Hall sensor can comprise exactly three contact regions or exactly four or exactly five or exactly six or exactly seven contact regions. The contact regions are preferably arranged along a straight line.

All distances between two consecutive contact regions can be exactly the same in the vertical Hall sensor having exactly five contact regions, or the distances between the three contact regions situated in the center are the same and the distances to the two outer contact regions are less than or greater than the two distances formed in the center.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a cross-sectional view of a vertical III-V Hall sensor;

FIG. 2 shows a top view of the example from FIG. 1; and

FIGS. 3a to 3f show top views of further examples.

### DETAILED DESCRIPTION

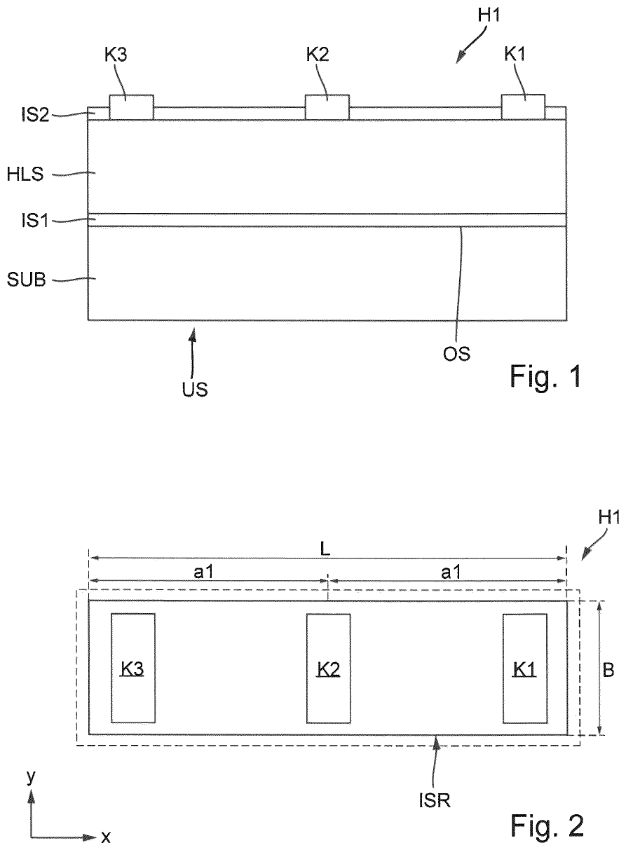

The illustration in FIG. 1 shows a cross-sectional view of a vertical III-V Hall sensor H1.

Hall sensor H1 has a substrate layer SUB with an upper side OS and an underside US. A first insulating layer IS1 is arranged on substrate layer SUB.

A III-V semiconductor layer HLS is formed on first insulating layer IS1. A second insulating layer IS2 is arranged on III-V semiconductor layer HLS.

In contrast to first insulating layer IS1, second insulating layer IS2 is provided with a structured design. In particular, second insulating layer IS2 has at least three openings designed as contact regions K1, K2, K3.

The at least three contact regions K1, K2, K3 are arranged along a straight line. It should be noted that III-V semiconductor layer HLS has an n-doping.

In addition, III-V semiconductor layer HLS or vertical III-V Hall sensor H1 has a peripheral insulation, which is not illustrated.

A top view of the example in FIG. 1 is shown in the illustration in FIG. 2. Only the differences from the illustration in FIG. 1 are explained below.

Vertical Hall sensor H1 has a peripheral insulation ISR in the shape of a rectangle. Contacts K1, K2, K3 arranged along the X axis are arranged entirely within the extension in the X direction and the Y direction.

It should be noted that outer rectangular-shaped insulation region ISR is not illustrated for reasons of clarity.

A distance a1 is formed between first contact K1 and second contact K2, and distance a1 is also formed between second contact K2 and third contact K3. In other words, two consecutive contacts K1, K2, and K2, K3, respectively, are arranged equidistantly from each other.

III-V semiconductor layer HLS or second insulating layer IS2 has a length L formed in the X direction and a width B formed in the Y direction.

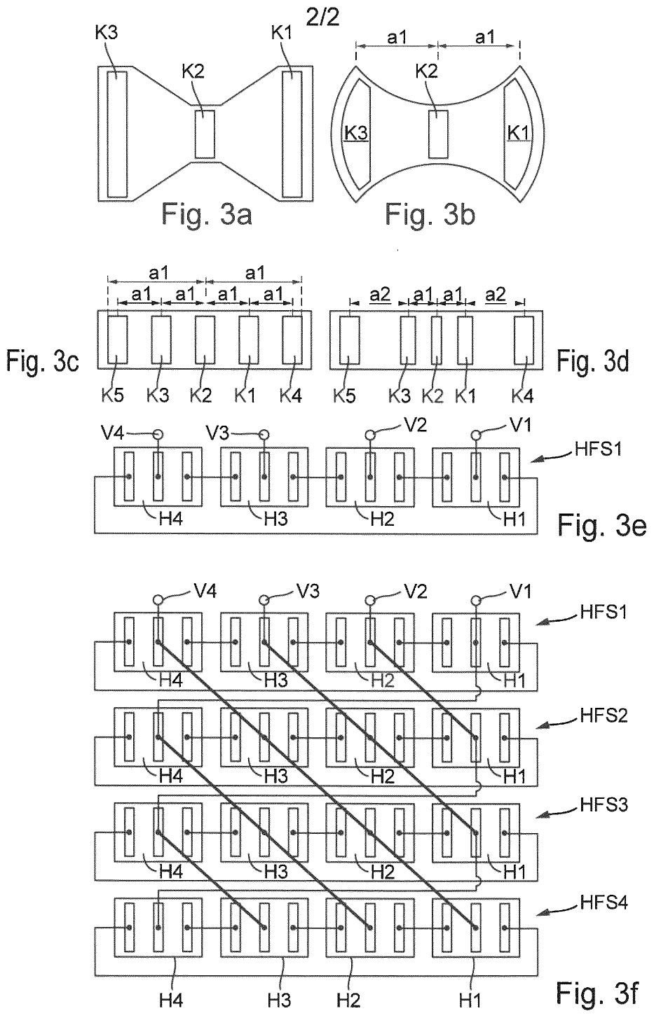

Top views of different examples of a vertical Hall sensor H2 are illustrated in FIGS. 3a through 3f. Only the differences from the preceding illustrations are explained below.

In contrast to the rectangular example in FIG. 2, the example in FIG. 3a has a fly-shaped or butterfly-shaped extension in the X direction with a peripheral outer edge. The outer edge is formed from a multiplicity of interconnected straight pieces. In the present case, the edge is formed from a total of twelve straight pieces.

III-V semiconductor region HLS has a smaller width in the region of second contact K2 than in the region around first contact K1 and third contact K3. The width of the III-V semiconductor region in the case of first contact K1 corresponds to or is the same size as the width of the III-V semiconductor region around third contact K3. All three contacts K1, K2, K3 have a rectangular shape, the width of particular contacts K1, K2, K3 being greater than the length in the X direction.

It is understood that, in the illustrated examples, the edge regions of contacts K1, K2, K3 are situated at a distance from the edge of the III-V semiconductor region.

In an example the contacts can be formed up to or beyond the edge of the III-V semiconductor region.

First contact K1 and third contact K3 are designed to have the same width in the Y direction and to be significantly wider than second contact K2. All three contacts K1, K2, K3 have a rectangular extension in the illustrated top view. The III-V Hall sensor region has a mirror symmetry with respect to a mirror axis running in the Y direction, which runs through a center of the second contact.

A butterfly-shaped extension having two wings is also shown in the illustration in FIG. 3b, a mirror axis formed in the Y direction running through the center of second contact K2.

The two wings are each provided with a crescent-shaped design. In other words, the outer edge of the entire III-V semiconductor region does not have any straight lines, but is formed by bow-shaped segments.

First contact K1 and third contact K3 are not rectangular, in contrast to second contact K2, but are made up of circle segments.

In contrast to the example of the III-V semiconductor region in FIG. 2, the example in FIG. 3c now comprises a total of five contacts K1 through K5, which are also formed in a straight line along the X direction.

Fourth contact K4 and fifth contact K5 are designed as outer contacts on the two head-side ends of III-V semiconductor region HLS. Distance a1 is formed between each of contacts K1 through K5. All five contacts K1 through K5 have a rectangular shape and are arranged equidistantly from each other.

In contrast to the example of the III-V semiconductor region in FIG. 3c, the two outer contacts K4 and K5 in the example in FIG. 3d are arranged at a distance a2 from each of directly adjacent contacts K3 and K1. Distance a2 is designed to be greater than distance a1. Although all five contacts K1 through K5 have a rectangular design, the rectangle of second contact K2, however, has the smallest length of all five contacts K1 through K5 in the X direction.

The two contacts K1 and K3 have the same length, the length of the two contacts K1, K3 being greater than the length of second contact K2. The length of the two outer contacts K4, K5 is the same size and, in each case, greater than the length of first contact K1 and third contact K3.

In the example illustrated in connection with FIG. 3e, a total of four individual III-V Hall sensors H1 through H4, each having three contacts K1, K2, K3, are arranged along a straight line formed in the X direction and connected to each other, only the differences from example in FIG. 2 being explained below. With the aid of the interconnection, it is achieved that III-V Hall sensors H1 through H4 are designed as a single large four-contact Hall sensor HFS1.

Each of outer contacts K1, K3 of each of the four III-V Hall sensors H1 through H4 are connected to form a ring with each of outer contacts K1, K3 of adjacent III-V Hall sensors K1 through H4. In other words, first contact K1 of first III-V Hall sensor H1 is connected to third contact K3 of fourth Hall sensor H4.

In the example illustrated in connection with FIG. 3f, a total of four large four-contact III-V Hall sensors HFS1, HFS2, HFS3, HFS4 are again shown, each made up of four individual III-V Hall sensors H1 through H4 connected to form a ring, each having three contacts K1, K2, K3 along a straight line formed in the X direction, only the differences from the example in FIG. 3e being explained below.

In total, the four large four-contact III-V Hall sensors HFS1 through HFS4 are arranged in four rows. Center contacts K1 in each case are each connected to the center contacts in an adjacent row. In other words, the four large four-contact Hall sensors are connected in parallel to each other.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A vertical III-V Hall sensor comprising:
a substrate layer with an upper side and an underside;
a first insulating layer formed on the substrate layer;
a III-V semiconductor layer formed on the first insulating layer; and
a second insulating layer formed on the III-V semiconductor layer, the second insulating layer being structured and having at least three openings designed as contact regions,
wherein the III-V semiconductor layer has a uniform thickness at least between the contact regions and including the contact regions;
wherein the III-V semiconductor layer has a length formed in an X direction and a width formed in a Y direction,
wherein at least three contact regions are arranged along a straight line;
wherein the III-V semiconductor layer has an n doping; and
wherein the III-V semiconductor layer has a peripheral insulation.

2. The vertical III-V Hall sensor according to claim 1, wherein the first insulating layer and/or the second insulating layer are made up of a III-V material or comprise a III-V material and are each not doped.

3. The vertical III-V Hall sensor according to claim 1, wherein the band gap of the first insulating layer and/or the second insulating layer is designed to be larger than a band gap of the III-V semiconductor layer.

4. The vertical III-V Hall sensor according to claim 1, wherein a thickness of the first insulating layer formed in a III-V material and/or a thickness of the second insulating layer formed in a III-V material is in a range between 2 nm and 100 nm.

5. The vertical III-V Hall sensor according to claim 1, wherein the first insulating layer and/or the second insulating layer comprise at least one of the elements In, Ga, and/or P or is/are made up of InGaP.

6. The vertical III-V Hall sensor according to claim 1, wherein the second insulating layer comprises a silicon oxide and/or a silicon nitride.

7. The vertical III-V Hall sensor according to claim 1, wherein the doping is uniform or variable over the thickness of the III-V semiconductor layer.

8. The vertical III-V Hall sensor according to claim 1, wherein the doping of the III-V semiconductor layer is in a range between 1·10¹⁴ 1/cm³ and 5·10¹⁷ 1/cm³ or in a range between 5·10¹⁴ 1/cm³ and 1·10¹⁶ 1/cm³ or in a range between 1·10¹⁵ 1/cm³ and 5·10¹⁵ 1/cm³.

9. The vertical III-V Hall sensor according to claim 1, wherein the III-V semiconductor layer has a thickness in a range between 0.5 μm and 50 μm or in a range between 1.0 μm and 20 μm or in a range between 3.0 μm and 10 μm.

10. The vertical III-V Hall sensor according to claim 1, wherein a ratio of length to width in the III-V semiconductor layer is greater than or equal to 1 or in a range between 1 and 50.

11. The vertical III-V Hall sensor according to claim 1, wherein a width of the III-V semiconductor layer is in a range between 1 μm and 20 μm or in a range between 3 μm and 10 μm.

12. The vertical III-V Hall sensor according to claim 1, wherein the III-V semiconductor layer has a uniform stoichiometry.

13. The vertical III-V Hall sensor according to claim 1, wherein the III-V semiconductor layer comprises GaAs or InGaAs or is made up of GaAs or InGaAs or InSb or InAs or GaSb.

14. The vertical III-V Hall sensor according to claim 1, wherein the III-V semiconductor layer has a trench as insulation.

15. The vertical III-V Hall sensor according to claim 1, wherein the distances between two directly consecutive contact regions are designed to be the same or different.

16. The vertical III-V Hall sensor according to claim 1, wherein a structured n-doped InGaP layer is arranged as a metallically conductive layer on the upper side of the III-V semiconductor layer.

17. The vertical III-V Hall sensor according to claim 1, wherein a highly conductive InGaP layer is arranged exclusively under a metal contact formed in the contact opening.
